(19) United States
(12) Patent Application Publication
(10) Pub. No.: US 2004/0264148 A1
(43) Pub. Date: Dec. 30, 2004

(54) Method and system for fan fold packaging

(76) Inventors: William Edward Burdick JR., Schenectady, NY (US); Sandeep Shrikant Tonapi, Niskayuna, NY (US); Joseph Alfred Iannotti, Glenville, NY (US); James Enrico Sabatini, Scotia, NY (US)

Correspondence Address: Patrick S. Yoder, FLETCHER YODER, P.O. Box 692289, Houston, TX, 77269-2289, US

(21) Appl. No.: 10/609,052

(22) Filed: Jun. 27, 2003

(51) Int. Cl. H01L 21/44; H05K 1/00; H05K 7/08

(52) U.S. Cl. 361/748; 438/125

(57) ABSTRACT

An electronic component assembly includes a flexible printed circuit, and further includes two components disposed on the flexible printed circuit, having electrical connections with the flexible printed circuit. The flexible layer is folded so that the components face each other and a thermal management device is disposed between the components. The thermal management device may be glued by a thermally conducting adhesive or otherwise held in a stable arrangement, in order to remove the heat generated from the components.

### BACKGROUND OF THE INVENTION

The present invention is directed towards electronic component packaging systems, and more specifically, towards packaging systems employing a flexible substrate layer and an integrated heat dissipation system.

Electronic goods are an omnipresent part of today's world. There exists an ever-increasing demand for high performance yet compact electronics. Electronic component packaging deals with positioning components to achieve best possible volume economy. As electronic packaging technologies have continued to reduce electronic packages in size and volume, the challenges to interconnect and assemble these packages have continued to rise. Printed circuit boards, which have been used in the past for interconnecting electronic components, are limited in their interconnect capability, the current state of the art for which is approximately 100 micron pitch. Recently, flexible interconnects have been utilized because of their ability to offer the most dense interconnect capability, the current state of the art being approximately 50 micron pitch. Thus, it is anticipated that flex-based interconnects will partially replace Printed Circuit Boards (PCB) and their corresponding device input/output (I/O) attachment configurations, such as, through-hole and Surface Mount Technology (SMT).

Similarly, because device I/O densities are increasing dramatically, linear arrays and peripherally located I/O devices are being replaced by area array I/O devices (either solid or depopulated configurations). Because one of the limits to device I/O density is device I/O pad geometry and the limit to device I/O pad geometry is driven by interconnect pitch, therefore, effectively, device I/O density is limited by interconnect pitch. As discussed earlier, flexible circuits are ideal for interconnecting devices with high I/O density because they offer the highest interconnect density. Furthermore, when configured with I/O in area arrays, flexible circuits could offer the highest device I/O interconnect density. However, novel devices based upon such combinations have not been proposed in the art and are not currently available.

Another method that has been developed to address the need for greater device functionality in minimum package areas and volumes is the use of 3D packaging, a packaging technology which interconnects devices, stacked one atop each other. However, such stacked approaches suffer from a critical shortcoming, that is, their dependency on “Known Good Die”. In current stacked approaches, for example, dies (which are typically integrated circuits) are assembled using a parallel process that produces an encapsulated module of multiple devices embedded within the stack. Upon completion of the stack process, the module is tested and, because the failed modules cannot be reworked or repaired, an undetected, untested or in-process defect in any of the devices results in a failed module. This leads to high rejection rate and consequently low yields.

Further, as with any packaging technology, method or approach that places devices in closer proximity, heat dissipation is an issue. The heat generated is detrimental for the component performance and can even lead to failure. Thus, existing packaging systems are limited in their ability to provide a suitable solution to the high interconnect density while effectively managing heat generated under operation. Hence, there exists a need for a compact packaging system that provides high interconnect density, is compatible with area array I/O devices and effectively manages thermal dissipation, and allows for rework and repair for the packaged modules.

### BRIEF DESCRIPTION OF THE INVENTION

The invention provides an approach to electronic device packaging designed to respond to such needs. According to an embodiment of the invention an electronic component assembly includes a flexible printed circuit, and further includes at least two electronic components disposed on the flexible printed circuit. The components are electrically connected with the flexible printed circuit. The flexible layer is folded so that the components face each other and a thermal management device is disposed between the components. The thermal management device may be secured by a thermally conducting adhesive or otherwise held in a stable arrangement, in order to remove the heat generated from the components.

Other embodiments may include a plurality of such structures. The flexible printed circuit may thus interconnect the variousdevices, and connect the devices with external circuitry. A wide variety of such assemblies may be thus constructed to form highly integrated packages with excellent packing densities and thermal management capabilities.

### BRIEF DESCRIPTION OF THE DRAWINGS

The foregoing and other advantages and features of the invention will become apparent upon reading the following detailed description and upon reference to the drawings in which:

FIG. 1 is a perspective view of the electronic component assembly according to one embodiment of the present invention;

FIG. 2 is a perspective view of the electronic component assembly of FIG. 1 with the flexible printed circuit extended, as during assembly or servicing;

FIG. 3 is a front elevational view of a similar electronic component assembly comprising two modular sections;

FIG. 4 is a front elevational view of the electronic component assembly of FIG. 3 with the flexible printed circuit extended, as during assembly or servicing;

FIG. 5 is a front elevational view of an alternative embodiment of the electronic component assembly comprising two modular sections and an inter-layer thermal management device;

FIG. 6 is a front elevational view of the electronic component assembly of FIG. 5 with the flexible printed circuit extended, as during assembly or servicing;

FIG. 7 is a front elevational view of a further alternative embodiment of the electronic component assembly comprising two modular sections, an inter-layer thermal management device and a second thermal management device;

FIG. 8 is a front elevational view of another alternative embodiment of the electronic component assembly comprising three modular sections;

FIG. 9 is a front elevational view of the electronic component assembly of FIG. 8 with the flexible printed circuit extended, as during assembly or servicing; and

FIG. 10 is a front elevational view of another embodiment of the electronic component assembly with multiple modular sections.

### DETAILED DESCRIPTION OF SPECIFIC EMBODIMENTS

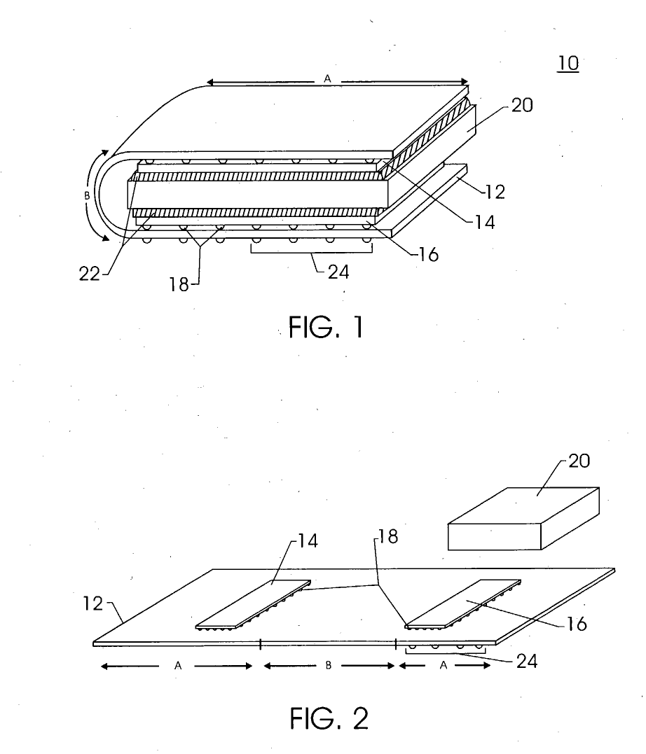

FIG. 1 illustrates an electronic component assembly 10 according to one embodiment of the present invention. The electronic component assembly 10 includes a foldable flexible printed circuit 12, such as for example, patterned metal interconnect on a polyimide film, e.g. Kapton™, or any other suitable materials or constructions. As will be appreciated by those skilled in the art, such flexible printed circuits may include a flexible insulative body in or on which a series of electrical conductors, printed conduction lines, embedded conductors or conductive traces, or the like are disposed for interconnection with imprinted circuits. It will be further appreciated that the flexible insulative body may be a flexible layer. The electronic component assembly 10 further includes a first component 14 and a second component 16. The components 14 and 16 may be any desired electronic components, such as memory devices, microprocessors, logic devices, among others. Similarly, the components may be identical to one another, or may have a similar functionality, or may be completely different in structure and function. The first and the second components 14 and 16 are connected to the flexible printed circuit 12 by electrical connections 18, such as solder joints as shown in the figure. It is to be appreciated here that solder joints generally represent the electrical connections 18, and are not restrictive to any embodiment of the invention.

An inter-component thermal management device 20 is positioned between components 14 and 16 for sinking, removing or isothermally stabilizing heat from or within the assembly. In the illustrated embodiment, device 20 is effectively shared by both components, thereby enhancing thermal management for both components while maintaining an extremely compact and dense package. It should be understood, moreover, that more than one device may be placed between the flexible printed circuit 12 and the thermal management device 20 rather than a single device on either position. Thus, even greater device packaging may be afforded.

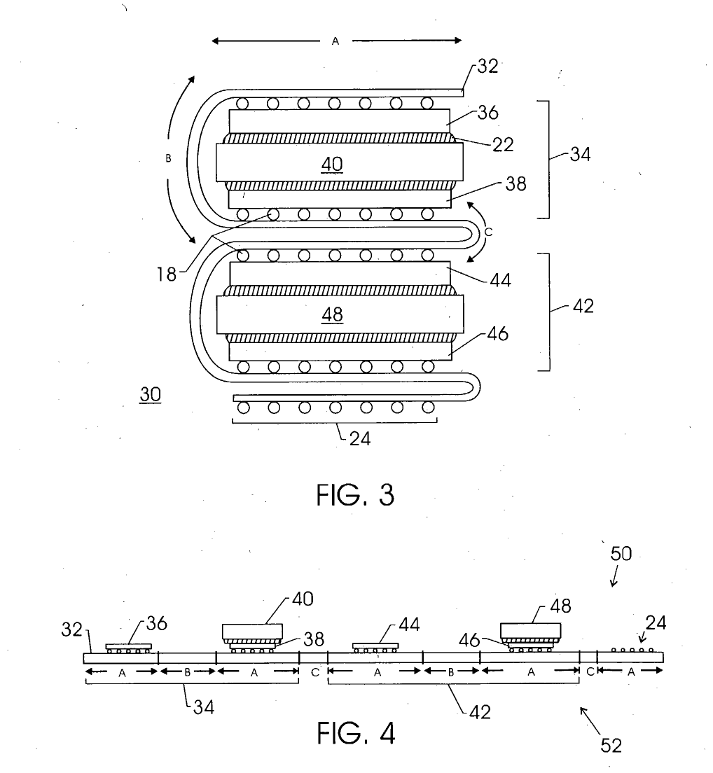

FIG. 2 shows the electronic component assembly 10 extended as it may be during assembly or servicing, to assist in appreciating the positioning of various components of FIG. 1. As illustrated, the first and the second components 14, 16 are positioned over the flexible printed circuit 12 adjacent to each other at a sufficient distance “b” to allow the flexible printed circuit to be folded, while providing sufficient material to accommodate the components and thermal management device combined heights. The length occupied by the components 14, 16 is designated as “a”. The inter-component thermal management device 20 is positioned so that it is sandwiched between the first and the second components 14, 16 as shown in FIG. 1. Though the inter-component thermal management device 20 is shown positioned over the second component 16, it actually may be positioned over either the first or the second electronic component 14, 16. A thermally conductive interface 22 lies between the inter-component thermal management device 20 and the components 14, 16, to enable thermal exchange. The thermal conductive interface 22 may be a thermal adhesive such as Ablefilm 564AK, Ablestick 84-1LMIT, or may merely refer to the physical contact between the inter-component thermal management device 20 and the components 14, 16. The flexible printed circuit 12 bearing the components 14, 16 and the inter-component thermal management device 20 is then fan folded to arrive at the configuration shown in FIG. 1. An external signal communication interface 24 is incorporated into the flexible printed circuit 12, such as by extension of the flexible printed circuit as shown in FIG. 1, and serves connect the electronic component assembly 10 to external components or circuitry. It is appreciated here that the external signal communication interface 24 may be formed on an extension of the flexible printed circuit as shown in FIG. 3. It is also appreciated that in other embodiments, more than one external signal communication interface may be incorporated in the flexible printed circuit, and further, the external signal communication interface can be incorporated at either end of the flexible printed circuit.

According to another embodiment of the invention, illustrated by FIG. 3, an electronic component assembly 30 comprises two modular sections 34, 42 each similar in construction to the electronic component assembly 10 of FIGS. 1 and 2. A first modular section 34 and a second modular section 42, are formed adjacent to each other on the flexible printed circuit 12, at a sufficient distance to accommodate a fold of the flexible printed circuit, as represented by the dimension “c”. Each modular section 34, 42 comprises-a first component 36, 44 and a second component 38, 46 positioned on the flexible printed circuit 32. The components of each section are interfaced with a respective thermal management device 40, 48 for removal of heat from the components during operation. Referring now to FIG. 4, each first component 36, 44 is separated from the respective second component 38, 46 by a distance “b”. Each component 36, 38, 44, 46 occupies a length “a” of the flexible printed-circuit. The modular sections 34, 42 are folded to form the electronic component assembly 30 of FIG. 3, bringing the components into thermally conductive contact or relation with the thermal management devices 40, 48.

As in the previous embodiment, more than one component may be situated on either side of each thermal management device. Moreover, such components may be similar or different in configuration and function. Thus, highly integrated overall circuits and packages may be provided in which the various components of each module are interfaced with one another and with external devices or circuits.

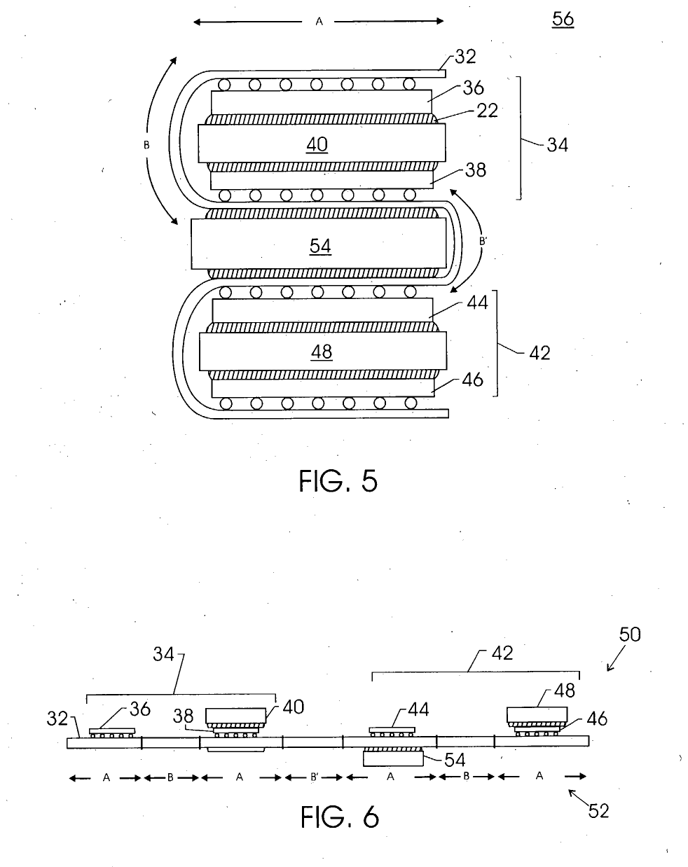

In a related embodiment of the invention, illustrated by FIGS. 5 and 6, modular sections 34, 42 are placed on a first side 50 of the flexible printed circuit 32 as previously, but are positioned farther apart to accommodate an inter-layer thermal management device 54. Referring to FIG. 6, the inter-layer heat dissipation device 54 is placed on the second side 52 of the flexible printed circuit 32, opposite to the first side 50. This positioning of the modular sections farther apart allows for incorporation of the inter-layer heat dissipation device 54 between the modular sections 34, 42. Folding the flexible printed circuit 32 of FIG. 6 about lengths “b” and “b′” forms a stack 56 of modular sections and inter-layer heat dissipation device as illustrated in FIG. 5. As will be appreciated by those skilled in the art, the inter-layer thermal management device serves to draw heat from the components through the flexible printed circuit, thereby further enhancing the thermal management offered by the thermal management devices 40and 48.

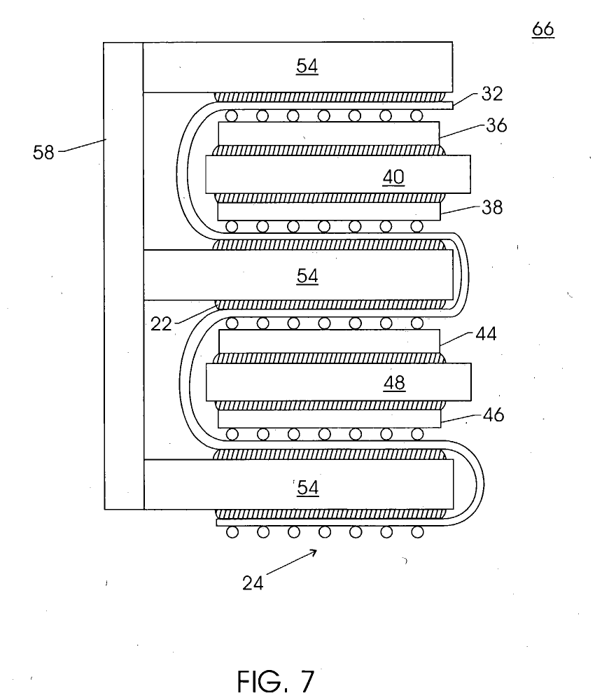

In a further related embodiment of the present invention, illustrated by FIG. 7, multiple inter-layer thermal management devices 54 are positioned alternate to modular sections, each of construction similar to that described above. The inter-layer thermal management devices 54 are thermally connected by at least one second thermal management device 58, forming the stack 66. It is to be appreciated here that the second thermal management device 58 may be connected to the inter-layer thermal management devices 54 along a side face of the stack, as shown, or along other faces of the stack. In particular, when such a second thermal management device 58 is provided in a plane generally parallel to the page of FIG. 7, the second thermal management device may be thermally coupled to one or all of devices, 40, 48, 54, without interfering with the flexible printed circuit. Additionally, such second thermal management devices 58 may be connected to all sides of the package, forming an enclosure around the components. Further, the second thermal management device 58 may be thermally connected to any of the inter-layer thermal management devices 54 or inter-component thermal management devices 40, 48 or a combination thereof.

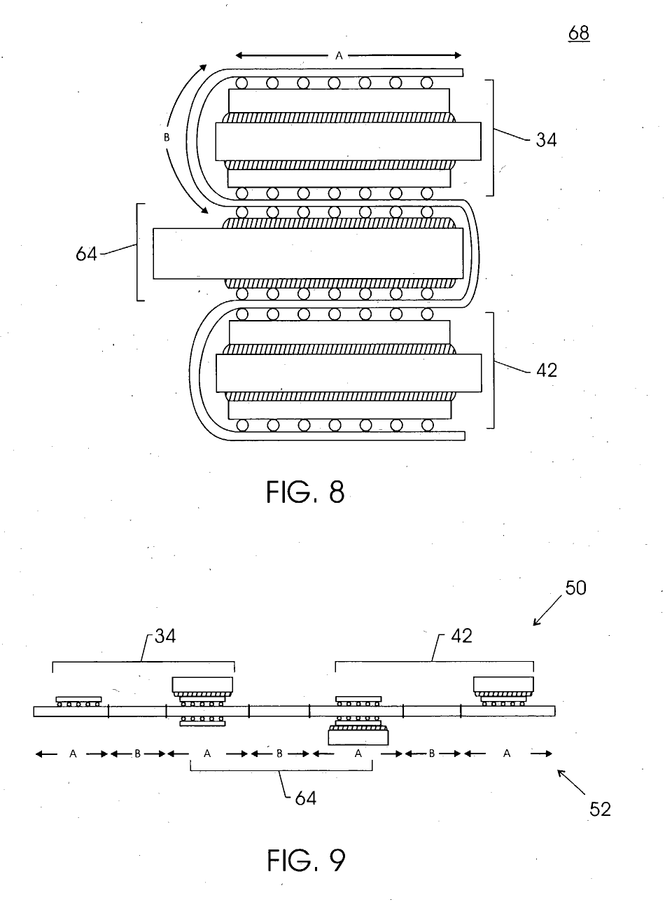

In yet another related embodiment of the present invention, illustrated by FIGS. 8 and 9, a third modular section 64 is positioned on the second side 52 of the flexible printed circuit 32, while the first and second modular sections 34, 42 are positioned on the first side 50 as indicated by FIG. 9. The third modular section 64 is similar to the first and second modular sections 34, 42, as can be seen in FIG. 9, but is formed on the second side 52 of the flexible printed circuit 32. The flexible printed circuit 32, populated with the components and the thermal management devices as shown in FIG. 9, is folded about the lengths “b” to form a stack 68 of modular sections.

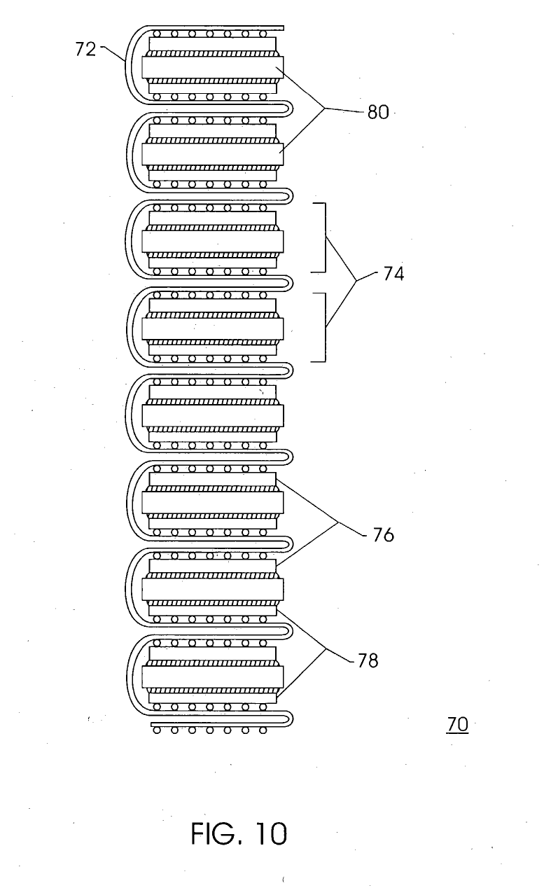

According to a further embodiment of the invention, FIG. 10 illustrates an electronic component assembly 70 having multiple modular sections 74. Each modular section 74 is similar to the ones previously illustrated, is formed on a continuous flexible printed circuit 72, and comprises a first component 76, a second component 78, and an inter-component thermal management device 80 in thermal connection with the components 76, 78. The loaded flexible printed circuit 72 is folded to form the stack or the electronic component assembly 70, which may be viewed as an array of electronic component assembly 30 of FIG. 3. Related embodiments may include an inter-layer thermal management device between the modular sections (array of stacks 56 or 66) or array of stack 68.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. An electronic component assembly, comprising:
a flexible printed circuit;
a first component electronically coupled with the flexible printed circuit;
a second component electronically coupled with the flexible printed circuit, the flexible printed circuit folded to position the components in generally mutually facing relation; and,
an inter-component thermal management device disposed between the components, in thermal relation with the components, for removing or stabilizing thermal energy from the components during operation.

2. The electronic component assembly of claim 1, wherein at least one of the components is an electronic device, a memory device, a logic device or a microprocessor.

3. The electronic component assembly of claim 1, wherein the components are selected from a group consisting of an electronic device, a memory device, a logic device and a microprocessor.

4. The electronic component assembly of claim 1, wherein the components have identical or similar functionality in operation.

5. The electronic component assembly of claim 1, wherein the components have a different functionality in operation.

6. The electronic component assembly of claim 1, the assembly further comprising at least one second thermal management device thermally connected to the inter-component thermal management device.

7. The electronic component assembly of claim 1, the assembly further comprising at least one external signal communication interface on the flexible printed circuit for communicating signals between the components and external circuits.

8. An electronic component assembly, comprising:
a flexible printed circuit;
a first modular section formed on the flexible printed circuit, comprising:
a first component electronically coupled with the flexible printed circuit;
a second component electronically coupled with the flexible printed circuit, the flexible printed circuit folded to position the components in generally mutually facing relation; and,
an inter-component thermal management device disposed between the components, in thermal relation with the components, for removing or stabilizing thermal energy from the components during operation;
a second modular section comprising:
a first component electronically coupled with the flexible printed circuit;
a second component electronically coupled with the flexible printed circuit, the flexible printed circuit folded to position the components in generally mutually facing relation; and,
a further inter-component thermal management device disposed between the components, in thermal relation with the components, for removing or stabilizing thermal energy from the components during operation, the flexible printed circuit being folded to form a stack of the modular sections.

9. The electronic component assembly of claim 8, wherein the components of the first modular section and the second modular section are disposed on a first side of the flexible printed circuit, and an inter-layer thermal management device is disposed on a second side of the flexible printed circuit opposite to the first side, the flexible printed circuit being folded to form a stack of the modular sections and the inter-layer heat dissipation device.

10. The electronic component assembly of claim 8, wherein the components of the first modular section and the second modular section are disposed on a first side of the flexible printed circuit and a third modular section, similar to the first and second modular sections, is disposed on a second side of the flexible printed circuit opposite to the first side, the flexible printed circuit being folded to form a stack of the modular sections.

11. The electronic component assembly of claim 9, the assembly further comprising at least one second thermal management device thermally connected to at least one of the inter-component or the inter-layer thermal management devices.

12. The electronic component assembly of claim 11, wherein the second thermal management device is positioned adjacent to at least one of a front face or a side face of the assembly.

13. An electronic component assembly, comprising:
a flexible printed circuit;
a plurality of modular sections formed on the flexible printed circuit, each modular section comprising:
a first component electronically coupled with the flexible printed circuit;
a second component electronically coupled with the flexible printed circuit, the flexible printed circuit folded to position the components in generally mutually facing relation; and,
an inter-component thermal management device disposed between the components, in thermal relation with the components, for removing or stabilizing thermal energy from the components during operation, the flexible printed circuit being folded to form a stack of the modular sections.

14. The electronic component assembly of claim 13, wherein the modular sections are disposed on a first side of the flexible printed circuit and at least one inter-layer thermal management device is disposed on the second side of the flexible printed circuit opposite to the first layer, the flexible printed circuit being folded to form a stack of the modular sections and the at least one inter-layer thermal management device.

15. The electronic component assembly of claim 14, wherein the modular sections and the inter-layer thermal management devices are positioned to result in an alternate arrangement of the modular sections and the inter-layer thermal management device in the stack.

16. The electronic component assembly of claim 13, wherein the modular sections are disposed on a first side of the flexible printed circuit and a further plurality of modular sections are disposed on the second side of the flexible printed circuit opposite to the first layer, the flexible printed circuit being folded to form a stack of the modular sections.

17. The electronic component assembly of claim i3, the assembly further comprising at least one second thermal management device thermally connected to at least one of the inter-component or the inter-layer thermal management devices.

18. The electronic component assembly of claim 17, wherein the second thermal management device is positioned adjacent to at least one of a front face or a side face of the assembly.

19. A method of manufacturing an electronic component assembly comprising:
disposing a first electronic component on a first side of a flexible printed circuit;
disposing a second electronic component on the first side of the flexible printed circuit;
folding the flexible printed circuit to bring the components into generally mutually facing relation; and
disposing an inter-component thermal management device between the components to remove or stabilize thermal energy from the components during operation.

20. The method of claim 19, wherein at least one of the components is a memory module.

21. The method of claim 19, wherein at least one of the components is a processor module.

22. The method of claim 19, wherein the first and second components are identical.

23. The method of claim 19, wherein the first and second components have a different functionality in operation.

24. The method of claim 19, further comprising disposing at least one second thermal management device in thermal connection to the inter-component thermal management device.

25. The method of claim 19, further comprising disposing an external signal communication interface on the flexible printed circuit for communicating signals between the components and external circuits.

26. A method of manufacturing an electronic component assembly comprising:
disposing a first electronic component of a first modular section on a first side of a flexible printed circuit;
disposing a second electronic component of the first modular section on the first side of the flexible printed circuit;
disposing a first electronic component of a second modular section on the first side of a flexible printed circuit;
disposing a second electronic component of the second modular section on the first side of the flexible printed circuit;
folding the flexible printed circuit to bring the components of the first modular section into generally mutually facing relation and the second modular section into generally mutually facing relation; and
disposing a first inter-component thermal management device between the components of the first modular section and disposing a second inter-component thermal management device between the components of the second modular section to remove or stabilize heat from the components during operation.

27. The method of claim 26, further comprising:
disposing an inter-layer thermal management device on a second side of the flexible printed circuit, opposite to the first side; and
folding the flexible printed circuit to dispose the inter-layer thermal management device between the first and second modular sections.

28. The method of claim 26, further comprising:
disposing a first electronic component of a third modular section on a second side of the flexible printed circuit, opposite to the first side;
disposing a second electronic component of the third modular section on the second side of the flexible printed circuit;
folding the flexible printed circuit to dispose the first and second electronic components of the third modular section into generally mutually facing relation; and
disposing an inter-component thermal management device between the components of the third modular section to remove or stabilize heat from the components during operation.

29. The method of claim 26, further comprising disposing at least one second thermal management device in thermal connection with at least one of the inter-component thermal management devices.

30. The method of claim 29, wherein the second thermal management device is positioned adjacent to at least one of a front face or a side face of the assembly.

31. A method of manufacturing an electronic component assembly comprising:
disposing a plurality of first electronic components on a first side of a flexible printed circuit, each of the first electronic components corresponding to a respective modular sections;
disposing a plurality of second electronic components on the first side of the flexible printed circuit, each of the second electronic components corresponding to the respective modular sections, so that each modular section comprises first and second electronic components;
folding the flexible printed circuit to bring the first and second components of the respective modular sections into generally mutually facing relation, thereby forming a stack of modular sections; and
disposing an inter-component thermal management device between the components of each modular section to remove or stabilize heat from the components during operation.

32. The method of claim 31, further comprising:
disposing a plurality of inter-layer thermal management devices on a second side of the flexible printed circuit opposite to the first layer; and
folding the flexible printed circuit to position an inter-layer thermal management device between adjacent pairs of the modular sections.

33. The method of claim 32, wherein the modular sections and the inter-layer thermal management devices are positioned to result in an alternate arrangement of the modular sections and the inter-layer thermal management devices in the stack.

34. The method of claim 31, further comprising the steps of:
disposing a further plurality of modular sections on a second side of the flexible printed circuit opposite to the first side; and
folding the flexible printed circuit to form a stack of the modular sections.

35. The method of claim 31, further comprising the step of disposing at least one second thermal management device in thermal connection with at least one of the inter-component or the inter-layer thermal management devices.

36. The method of claim 31, wherein the second thermal management device is positioned adjacent to at least one of a front face or a side face of the assembly.
